(19) United States
(12) Patent Application Publication
(10) Pub. No.: US 2018/0190520 A1
(43) Pub. Date: Jul. 5, 2018

(54) COMPOSITE HEAT-DISSIPATING SUBSTRATE

(71) Applicant: LUXNET CORPORATION, Zhongli City (TW)

(72) Inventors: Hsing-Yen LIN, Taoyuan County (TW); Pi-Cheng LAW, Taoyuan County (TW); Po-Chao HUANG, Taoyuan County (TW); Bo-Wei LIU, Taoyuan County (TW); Ya-Hsin DENG, Taoyuan County (TW); Hua-Hsin SU, Taoyuan County (TW)

(21) Appl. No.: 15/795,992

(22) Filed: Oct. 27, 2017

(30) Foreign Application Priority Data
Dec. 30, 2016 (TW) 105220109

(51) Int. Cl. H01L 21/67; F21V 29/89; B32B 9/00; C22C 32/00

(52) U.S. Cl. CPC H01L 21/67103; C22C 32/0021; B32B 9/005; F21V 29/89

(57) ABSTRACT

The present invention provides a composite heat-dissipating substrate structure, comprising: a heat-dissipating substrate and a heat-conducting metal layer. The heat-dissipating substrate includes a substrate body and a socket formed on the substrate body; and the heat-conducting metal layer widely covers the socket of the substrate body and have one side formed as a loaded side on which a laser semiconductor is to be mounted and a opposite side formed as a heat-dissipating side, so that after the loaded side absorbs heat from the laser semiconductor, the heat-dissipating side reverse to the heat-conducting metal layer diffuses the heat to the heat-dissipating substrate.

### BACKGROUND OF THE INVENTION

### 1. Technical Field

The present invention relates to a composite heat-dissipating substrate structure, more particularly to a high thermal conductivity composite heat-dissipating substrate structure.

### 2. Description of Related Art

Recently, with the technical development of semiconductor processes, many semiconductor devices have been made more compact and become maturer in terms of power and data transfer rate. In the field of optical communication, laser diodes are usually used as a transmitter of signals. With good directionality and high output power, laser diodes are extensively used for optical communication. As a high-power semiconductor device, laser diodes tend to generate heat when operating. If the heat is not released timely, the junction of the laser diode can become hot and this can jeopardize the device's working efficiency. Due to thermoelectric conversion, as the efficiency decreases, more heat will be accumulated and make the laser diode even hotter, in turn ruining the laser diode's reliability, optical output power, and even service life.

In practice, for ensuring a laser diode device's working efficiency under high temperature, a typical approach is to use a heat-dissipating substrate made of a material with high thermal conductivity. Such a heat-dissipating substrate facilitates heat dissipation of the laser diode it carries, so as to maintain proper operational temperature. However, as the heat-dissipating substrate is usually made of ceramic materials, when working with a high-power laser diode, it is likely that the ceramic substrate cannot release the heat generated by the laser diode timely. Accumulation of the heat will make the temperature keep rising, and finally bring about adverse effects on the laser diode's working efficiency and service life. Therefore, the inventor of the present invention has paid effort to devise a heat-dissipating substrate that effectively addresses the problem related to high heat generated by high-power laser diodes.

### SUMMARY OF THE INVENTION

In view of this, the objective of the present invention is to solve the problems seen in conventional heat-dissipating substrates associated with high heat generated when high-power laser diodes operate, such as inferior work efficiency and service time of the affected laser diodes.

To achieve the objective, the present invention provides a composite heat-dissipating substrate structure, comprising: a heat-dissipating substrate and a heat-conducting metal layer. The heat-dissipating substrate includes a substrate body and a socket formed on the substrate body. The heat-conducting metal layer widely covers the socket of the substrate body and have one side formed as a loaded side on which a laser semiconductor is to be mounted and a opposite side formed as a heat-dissipating side, so that after the loaded side absorbs heat from the laser semiconductor, the heat-dissipating side reverse to the heat-conducting metal layer diffuses the heat to the heat-dissipating substrate.

Further, the composite heat-dissipating substrate structure comprises a metal solder layer located between the laser semiconductor and the heat-conducting metal layer for fixedly attaching the laser semiconductor to the heat-conducting metal layer.

Further, the laser semiconductor is an edge emitting laser diode.

Further, the heat-dissipating substrate is made of aluminum nitride (AlN) materials.

Further, the heat-conducting metal layer is made of copper (Cu) materials.

Further, the heat-dissipating substrate is made of aluminum nitride (AlN) materials and the heat-conducting metal layer is made of copper (Cu) materials.

Further, the socket has a flat surface and the heat-dissipating side of the heat-conducting metal layer is in close fit with the flat surface of the socket.

Further, the socket includes one or more first micro-structure(s). and the heat-dissipating side of the heat-conducting metal layer is provided with one or more second micro-structure(s) corresponding to the first micro-structure(s); the combination between the second micro-structure(s) and the first micro-structure(s) increases the contact area between the heat-conducting metal layer and the heat-dissipating substrate.

Further, the heat-conducting metal layer has a thickness not greater than half of the thickness of the heat-dissipating substrate.

Further, the heat-dissipating substrate has a stepped portion formed at two sides of the socket and different from the socket in height, and the stepped portion has a width greater than 70 μm.

To achieve the objective, the present invention provides a composite heat-dissipating substrate structure, comprising: a heat-dissipating substrate and a heat-conducting metal layer. The heat-dissipating substrate includes a substrate body and a carrying surface formed on the substrate body. The heat-conducting metal layer widely covers the carrying surface of the substrate body and have one side formed as a loaded side on which a laser semiconductor is to be mounted and a opposite side formed as a heat-dissipating side, so that after the loaded side absorbs heat from the laser semiconductor, the heat-dissipating side reverse to the heat-conducting metal layer diffuses the heat to the heat-dissipating substrate.

Further, the composite heat-dissipating substrate structure comprises a metal solder layer located between the laser semiconductor and the heat-conducting metal layer for fixedly attaching the laser semiconductor to the heat-conducting metal layer.

Further, the laser semiconductor is an edge emitting laser diode.

Further, the heat-dissipating substrate is made of aluminum nitride (AlN) materials.

Further, the heat-conducting metal layer is made of copper (Cu) materials.

Further, the heat-dissipating substrate is made of aluminum nitride (AlN) materials and the heat-conducting metal layer is made of copper (Cu) materials.

Further, the carrying surface is a flat surface and the heat-dissipating side of the heat-conducting metal layer is in close fit with the carrying surface.

Further, the carrying surface includes one or more first micro-structure(s), and the heat-dissipating side of the heat-conducting metal layer is provided with one or more second micro-structure(s) corresponding to the first micro-structure(s); the combination between the second micro-structure(s) and the first micro-structures) increases the contact area between the heat-conducting metal layer and the heat-dissipating substrate.

Further, the heat-conducting metal layer has a thickness not greater than a half of the thickness of the heat-dissipating substrate.

Further, the heat-dissipating substrate has an additional carrying surface reverse to the carrying surface on which an additional heat-conducting metal layer is deposited, and the additional carrying surface is closely combined with a heat-conducting surface of the additional heat-conducting metal layer.

Further, the additional carrying surface has one or more third micro-structure(s) and the heat-conducting surface of the additional heat-conducting metal layer has one or more fourth micro-structure(s) corresponding to the third micro-structure(s); the combination between the fourth micro-structure(s) and the third micro-structure(s) increases the contacting area between the additional heat-conducting metal layer and the heat-dissipating substrate.

Therefore, comparing to the prior art, the present invention has advantages described as below:

1. The present invention uses the heat-conducting metal layer that has relatively high heat-conducting capacity to absorb the heat generated by a laser diode in advance, and then makes the absorbed heat rapidly transferred to the heat-dissipating substrate by means of contact between the heat-conducting metal layer and the heat-dissipating substrate.

2. By limiting the heat-conducting metal layer in thickness, the present invention solves the problem that the heat-conducting metal layer changes the position of the laser diode due to thermal expansion effect and brings adverse effects to the laser diode's optical coupling efficiency.

### BRIEF DESCRIPTION OF THE DRAWINGS

FIG. 1 shows perspective schematic view of the first embodiment of the present invention.

FIG. 2 shows exploded view of the first embodiment of the present invention.

FIG. 3 shows cross-sectional schematic view of the first embodiment of the present invention.

FIG. 4 shows a cross-sectional schematic view of the second embodiment of the present invention.

FIG. 5 shows perspective schematic view of the third embodiment of the present invention.

FIG. 6 shows exploded view of the third embodiment of the present invention.

FIG. 7 shows cross-sectional schematic view of the third embodiment of the present invention.

FIG. 8 shows cross-sectional schematic view of the forth embodiment of the present invention.

### DETAILED DESCRIPTION OF THE EMBODIMENT OF THE INVENTION

Descriptions and techniques of the present invention would be illustrated in detail with reference to the accompanying drawings herein. Furthermore, for easier illustrating, the drawings of the present invention are not a certainly the practical proportion and are not limited to the scope of the present invention.

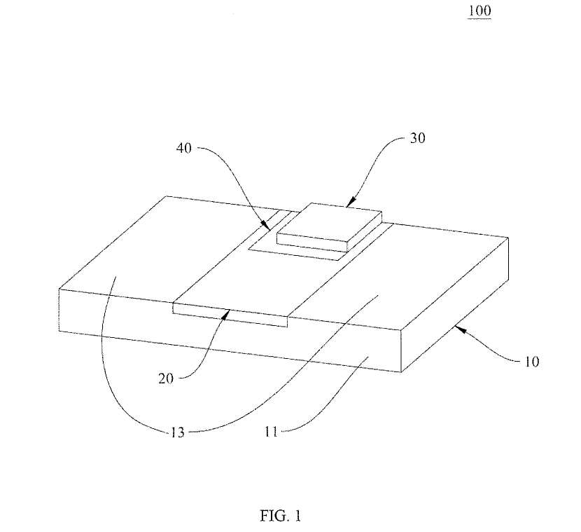

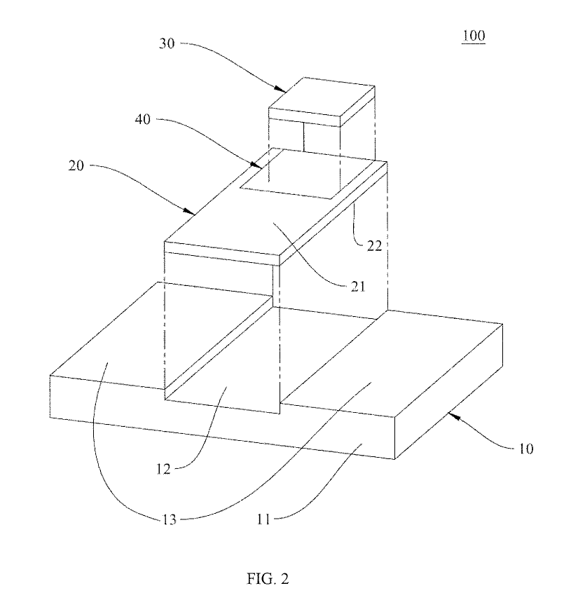

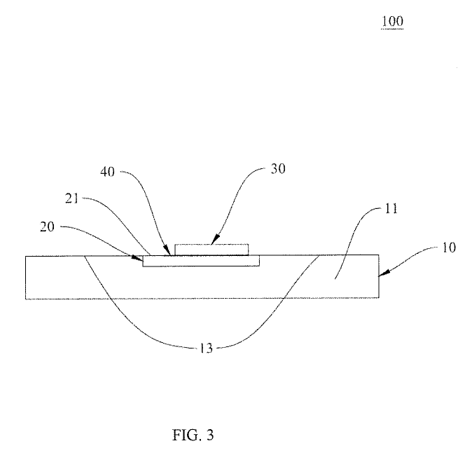

Please refer to FIG. 1, FIG. 2, and FIG. 3 for perspective, exploded, and cross-sectional views of the first embodiment of the present invention.

The present embodiment provides a composite heat-dissipating substrate structure 100. The composite heat-dissipating substrate structure 100 comprises a heat-dissipating substrate 10 and a heat-conducting metal layer 20 deposited on the heat-dissipating substrate 10. The heat-dissipating substrate 10 comprises a substrate body 11 and a socket 12 formed on the substrate body 11.

The heat-dissipating substrate 10 can be made of, for example, aluminum nitride (AlN), silicon carbide (SiC), aluminum oxide (Al₂O₃), or any compounds or composites containing the foregoing materials, and the present invention places no limitation thereon. In a preferred embodiment, the heat-dissipating substrate 10 is made of aluminum nitride (AlN). With high heat-transferring capacity and low coefficient of thermal expansion (CTE), aluminum nitride is structurally stable under thermal variation, hardly with thermal expansion or contraction, which prevents the heat-dissipating substrates made of aluminum nitride deform and generate the offset beams under thermal variation.

The heat-conducting metal layer 20 is deposited on the substrate body 11, and widely covers the flat surface of the socket 12 on the substrate body 11. The heat-conducting metal layer 20 comprises a loaded side 21 and a heat-dissipating side 22. The heat-dissipating side 22 is in close fit with the flat surface of the socket 12. The loaded side 21 is to be loaded with a laser semiconductor 30 and absorbs heat generated by the laser semiconductor 30. The heat is then transferred to the heat-dissipating side 22 before diffusing to the heat-dissipating substrate 10. The heat-conducting metal layer 20 can be made of, for example, highly thermally conductive copper (Cu), copper tungsten (CuW), copper alloy, copper molybdenum (CuMo), aluminum (Al), aluminum alloy, diamond copper (Dia Cu), heat-dissipating ceramic or other materials having high heat-conductive capacity, and the present invention places no limitation thereon. In a preferred embodiment, the heat-conducting metal layer 20 is made of copper (Cu). Copper is highly thermally conductive, and can instantly receive heat from the laser semiconductor 30 and rapidly transfer the heat to the heat-dissipating substrate 10.

In one preferred embodiment, the laser semiconductor 30 is an edge emitting laser diode. The laser semiconductor 30 is mounted on the heat-conducting metal layer 20, and is firmly fixed to the heat-conducting metal layer 20 by means of a metal solder layer 40. The metal solder layer 40 can be made of, for example, gold (Au), tin (Sn), gold-tin alloy, other metals or any alloys or composites containing the foregoing materials, and the present invention places no limitation thereon.

In one preferred embodiment, for ensuring proper structural strength of the heat-dissipating substrate 10, the heat-conducting metal layer 20 should have a thickness not greater than half of the thickness of the heat-dissipating substrate 10. The vertical offset of the heat-conducting metal layer 20 caused by thermal expansion should be limited. In another preferred embodiment, the heat-dissipating substrate 10 has a stepped portion 13 formed at two sides of the socket 12 and different from the socket 12 in height. The stepped portion 13 has a width greater than 70 nm so as to ensure proper structural strength of the heat-dissipating substrate 10.

In the present embodiment, the heat-conducting metal layer 20 is a relatively thin metal layer. In the process of absorbing the heat from the laser semiconductor 30 in advance, the vertical offset of the laser semiconductor 30 is reduced, and the distance between the heat-conducting metal layer 20 and the socket 12 is shortened, so the heat can be transferred to the heat-dissipating substrate 10 through the heat-dissipating side 22 rapidly.

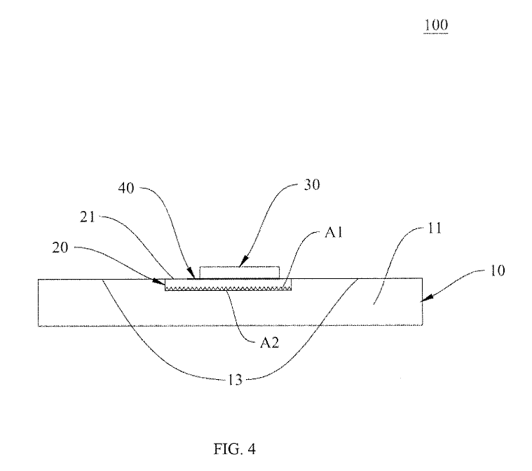

Please also refer to FIG. 4 for a cross-sectional view of the second embodiment of the present invention.

In the present embodiment, the socket 12 of the heat-dissipating substrate 10 includes one or more first micro-structure(s) A1, and the heat-dissipating side 22 of the heat-conducting metal layer 20 is provided with one or more second micro-structure(s) A2 corresponding to the first micro-structure(s) A1. The combination between the second micro-structure(s) A2 and the first micro-structure(s) A1 increases the contact area between the heat-conducting metal layer 20 and the heat-dissipating substrate 10, so that the heat-conducting metal layer 20 can transfer heat to the heat-dissipating substrate 10 more easily.

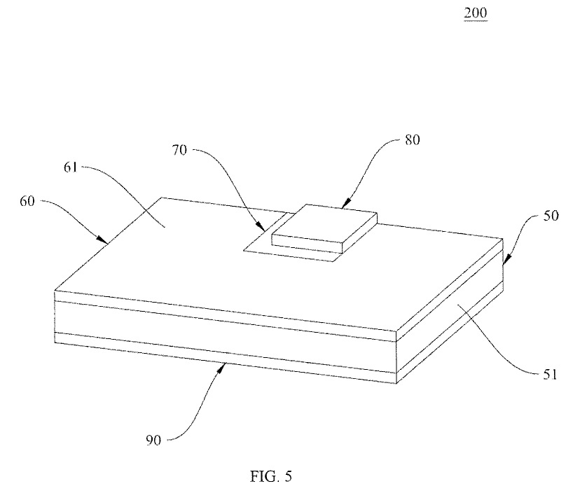

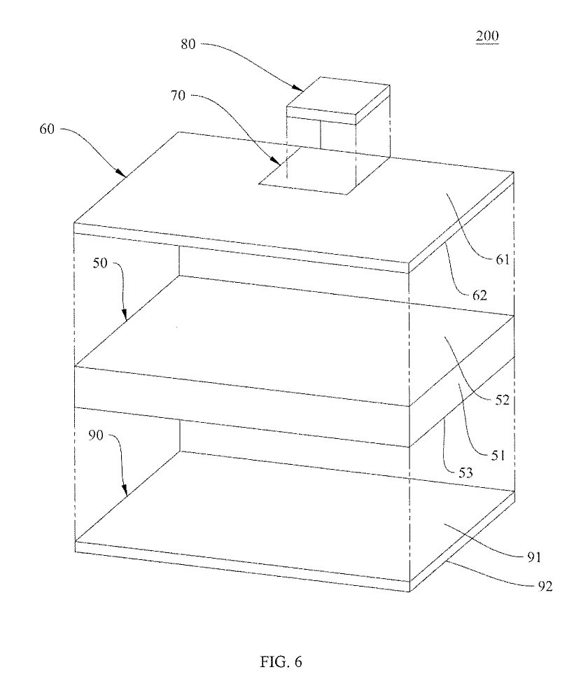

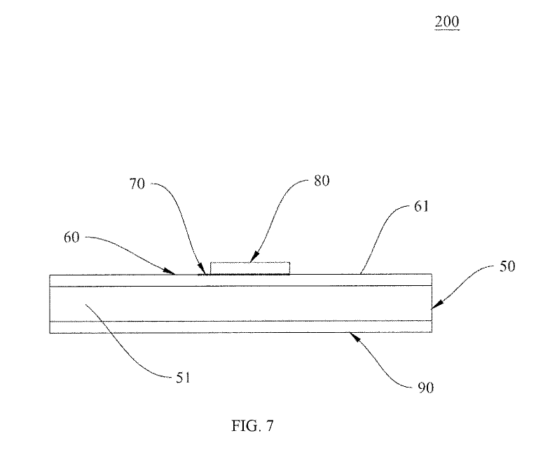

Please refer to FIG. 5, FIG. 6, and FIG. 7 for perspective, exploded, and cross-sectional views of the third embodiment of the present invention.

The present embodiment is different from the first embodiment and the second embodiment solely on the heat-dissipating substrate structure, and all the similarities will not be discussed any further hereinafter.

The present embodiment provides a composite heat-dissipating substrate structure 200. The composite heat-dissipating substrate structure 200 comprises a heat-dissipating substrate 50 and a heat-conducting metal layer 60 deposited on the heat-dissipating substrate 50. The heat-dissipating substrate 50 comprises a substrate body 51 and a carrying surface 52 formed on the substrate body 51. The heat-conducting metal layer 60 widely covers the carrying surface 52 of the substrate body 51. The heat-conducting metal layer 60 comprises a loaded side 61 and a heat-dissipating side 62 formed on two opposite sides. The loaded side 61 is configured to carry a laser semiconductor 80 for absorbing heat generated by the laser semiconductor 80 and transferring the heat to the heat-dissipating side 62, after which the heat is diffused to the heat-dissipating substrate 50 through the heat-dissipating side 62.

The laser semiconductor 80 is mounted on the heat-conducting metal layer 60, and is firmly fixed to the heat-conducting metal layer 60 by means of a metal solder layer 70. The metal solder layer 70 can be made of, for example, gold (Au), tin (Sn), gold-tin alloy, other metals or any alloys or composites containing the foregoing materials, and the present invention places no limitation thereon.

The heat-dissipating substrate 50 further comprises additional carrying surface 53 at the lower side of the heat-dissipating substrate 50, and there is additional heat-conducting metal layer 90 deposited on this additional carrying surface 53, so that a heat-conducting surface 91 of this additional heat-conducting metal layer 90 is in close fit with the additional carrying surface 53. This allows heat from the heat-dissipating substrate 50 to be transferred to the additional heat-conducting metal layer 90 timely and then diffused to the heat-transferring surface 92. The heat-transferring surface 92 can afterward spread the heat out by means of thermal conduction, thermal convection, or thermal radiation, and the present invention places no limitation thereon.

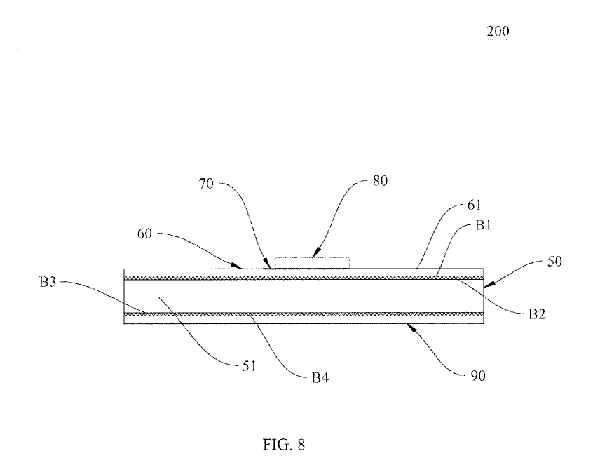

Please also refer to FIG. 8 for a cross-sectional view of the fourth embodiment of the present invention.

In the preferable embodiment, the heat-conducting metal layer 60 and the additional heat-conducting metal layer 90 should have a thickness not greater than half of the thickness of the heat-dissipating substrate 50 respectively.

In the present embodiment, the heat-conducting metal layer 60 and the additional heat-conducting metal layer 90 are relatively thin metal layers. In the process of absorbing the heat from the laser semiconductor 80, the vertical offset of the laser semiconductor 80 is reduced, and the distances between the heat-conducting metal layer 60 together with the additional heat-conducting metal layer 90 and the carrying surfaces 52, 53 are shortened, so the heat can be transferred to the heat-dissipating substrate 50 through the heat-dissipating side 62 rapidly. The additional heat-conducting metal layer 90 can contact a substrate, a casing or a heat-dissipating material or a heat-dissipating medium to rapidly absorb the heat accumulated in the heat-dissipating substrate 50 and guide the heat outward.

For increased contacting area between the heat-conducting metal layer 60 and the heat-dissipating substrate 50, the carrying surface 52 of the heat-dissipating substrate 50 is provided with one or more first micro-structure(s) B1, and the heat-dissipating side 62 of the heat-conducting metal layer 60 is provided with a second micro-structure(s) B2 corresponding to the first micro-structure(s) B1. The combination between the second micro-structure(s) B2 and the first micro-structure(s) B1 increases the contacting area between the heat-conducting metal layer 60 and the heat-dissipating substrate 50. The additional carrying surface 53 of the heat-dissipating substrate 50 has one or more third micro-structure(s) B3. The heat-conducting surface 91 of the additional heat-conducting metal layer 90 has a fourth micro-structure(s) B4 corresponding to the third micro-structure(s) B3. The combination between the fourth micro-structure(s) B4 and the third micro-structure(s) B3 increases the contacting area between the heat-conducting metal layer 90 and the heat-dissipating substrate 50. With the combination between the first micro-structure(s) B1 and the second micro-structure(s) B2, as well as the combination between the third micro-structure(s) B3 and the fourth micro-structure(s) B4, the heat-dissipating substrate 50 has improved overall heat-conducting capacity. This allows the heat-dissipating substrate 50 to transfer heat more rapidly and efficiently.

In conclusion, the present invention uses the heat-conducting metal layer that has relatively high heat-conducting capacity to absorb the heat generated by a laser diode in advance, and then makes the absorbed heat rapidly transferred to the heat-dissipating substrate by means of contact between the heat-conducting metal layer and the heat-dissipating substrate. By limiting the heat-conducting metal layer in thickness to reduce thermal expansion deformation, the present invention solves the problem that the heat-conducting metal layer changes the light emitting position of the laser diode due to thermal expansion effect and brings adverse effects to the laser diode's optical coupling efficiency.

The present invention is more detailed illustrated by the above preferable example embodiments. While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

What is claimed is:

1. A composite heat-dissipating substrate structure, comprising:
a heat-dissipating substrate, including a substrate body and a socket formed on the substrate body; and
a heat-conducting metal layer, widely covering the socket of the substrate body and having one side formed as a loaded side on which a laser semiconductor is to be mounted and a opposite side formed as a heat-dissipating side, so that after the loaded side absorbs heat from the laser semiconductor, the heat-dissipating side reverse to the heat-conducting metal layer diffuses the heat to the heat-dissipating substrate.

2. The composite heat-dissipating substrate structure of claim 1, further comprising a metal solder layer located between the laser semiconductor and the heat-conducting metal layer for fixedly attaching the laser semiconductor to the heat-conducting metal layer.

3. The composite heat-dissipating substrate structure of claim 1, wherein the laser semiconductor is an edge emitting laser diode.

4. The composite heat-dissipating substrate structure of claim 1, wherein the heat-dissipating substrate is made of aluminum nitride (AlN) materials.

5. The composite heat-dissipating substrate structure of claim 1, wherein the heat-conducting metal layer is made of copper (Cu) materials.

6. The composite heat-dissipating substrate structure of claim 1, wherein the heat-dissipating substrate is made of aluminum nitride (AlN) materials and the heat-conducting metal layer is made of copper (Cu) materials.

7. The composite heat-dissipating substrate structure of claim 1, wherein the socket has a flat surface and the heat-dissipating side of the heat-conducting metal layer is in close fit with the flat surface of the socket.

8. The composite heat-dissipating substrate structure of claim 1, wherein the socket includes one or more first micro-structure(s), and the heat-dissipating side of the heat-conducting metal layer is provided with one or more second micro-structure(s) corresponding to the first micro-structure(s); the combination between the second micro-structure(s) and the first micro-structure(s) increases the contact area between the heat-conducting metal layer and the heat-dissipating substrate.

9. The composite heat-dissipating substrate structure of claim 1, wherein the heat-conducting metal layer has a thickness not greater than half of the thickness of the heat-dissipating substrate.

10. The composite heat-dissipating substrate structure of claim 1, wherein the heat-dissipating substrate has a stepped portion formed at two sides of the socket and different from the socket in height, and the stepped portion has a width greater than 70 μm.

11. A composite heat-dissipating substrate structure, comprising:
a heat-dissipating substrate, including a substrate body and a carrying surface formed on the substrate body; and
a heat-conducting metal layer, widely covering the carrying surface of the substrate body and having one side formed as a loaded side on which a laser semiconductor is to be mounted and a opposite side formed as a heat-dissipating side, so that after the loaded side absorbs heat from the laser semiconductor, the heat-dissipating side reverse to the heat-conducting metal layer diffuses the heat to the heat-dissipating substrate by means of contact diffusion.

12. The composite heat-dissipating substrate structure of claim 11, further comprising a metal solder layer located between the laser semiconductor and the heat-conducting metal layer for fixedly attaching the laser semiconductor to the heat-conducting metal layer.

13. The composite heat-dissipating substrate structure of claim 11, wherein the laser semiconductor is an edge emitting laser diode.

14. The composite heat-dissipating substrate structure of claim 11, wherein the heat-dissipating substrate is made of aluminum nitride (AlN) materials.

15. The composite heat-dissipating substrate structure of claim 11, wherein the heat-conducting metal layer is made of copper (Cu) materials.

16. The composite heat-dissipating substrate structure of claim 11, wherein the heat-dissipating substrate is made of aluminum nitride (AlN) materials and the heat-conducting metal layer is made of copper (Cu) materials.

17. The composite heat-dissipating substrate structure of claim 11, wherein the carrying surface is a flat surface and the heat-dissipating side of the heat-conducting metal layer is in close fit with the carrying surface.

18. The composite heat-dissipating substrate structure of claim 11, wherein the carrying surface includes one or more first micro-structure(s), and the heat-dissipating side of the heat-conducting metal layer is provided with one or more second micro-structure(s) corresponding to the first micro-structure(s); the combination between the second micro-structure(s) and the first micro-structure(s) increases the contact area between the heat-conducting metal layer and the heat-dissipating substrate.

19. The composite heat-dissipating substrate structure of claim 11, wherein the heat-conducting metal layer has a thickness not greater than half of the thickness of the heat-dissipating substrate.

20. The composite heat-dissipating substrate structure of claim 11, wherein the heat-dissipating substrate has an additional carrying surface reverse to the carrying surface on which an additional heat-conducting metal layer is deposited, and the additional carrying surface is closely combined with a heat-conducting surface of the additional heat-conducting metal layer.

21. The composite heat-dissipating substrate structure of claim 20, wherein, the additional carrying surface has one or more third micro-structure(s) and the heat-conducting surface of the additional heat-conducting metal layer has one or more fourth micro-structure(s) corresponding to the third micro-structure(s); the combination between the fourth micro-structure(s) and the third micro-structure(s) increases the contacting area between the additional heat-conducting metal layer and the heat-dissipating substrate.
